(19) United States
(12) Patent Application Publication
(10) Pub. No.: US 2026/0229455 A1
(43) Pub. Date: Aug. 6, 2026

(54) MULTI-CHARGED PARTICLE BEAM WRITING METHOD, AND NON-TRANSITORY COMPUTER-READABLE STORAGE MEDIUM STORING A PROGRAM

(71) Applicant: NuFlare Technology, Inc., Yokohama-shi (JP)

(72) Inventor: Haruyuki NOMURA, Yokohama-shi (JP)

(73) Assignee: NuFlare Technology, Inc., Yokohama-shi (JP)

(21) Appl. No.: 19/407,066

(22) Filed: Dec. 3, 2025

(30) Foreign Application Priority Data
Feb. 5, 2025 (JP) 2025-017903

(51) Int. Cl. H01J 37/317; H01J 37/304

(52) U.S. Cl. CPC H01J 37/3171; H01J 37/3045; H01J 2237/24507; H01J 2237/31764

(57) ABSTRACT

According to one aspect of the present invention, a multi-charged particle beam writing method includes generating bitmap data defining values each depending on a dose of each pixel of a plurality of pixels, for each of a plurality of writing regions, on a target object, each of which is composed of meshed-divided regions being the plurality of pixels and which are offset from each other by a size equal to or smaller than a size of the each pixel; and performing writing, based on two or more bitmap data in a plurality of bitmap data, to pixels each being in a different one of writing regions each corresponding to one of the two or more bitmap data with a plurality of shots of a same beam in multiple charged particle beams during one tracking control, while repeating a cycle of resetting a deflection amount after each tracking control.

### CROSS-REFERENCE TO RELATED APPLICATION

This application is based upon and claims the benefit of priority from prior Japanese Patent Application No. 2025-017903 filed on Feb. 5, 2025 in Japan, the entire contents of which are incorporated herein by reference.

### BACKGROUND OF THE INVENTION

### Field of the Invention

Embodiments of the present invention relate to a multi-charged particle beam writing method and a program. For example, embodiments of the present invention relate to a method for correcting a positional deviation of a beam array at the time of multiple writing by a multiple beam writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With regard to multiple beam writing, the bitmap shift method is examined as a method for reducing gray level errors (e.g., refer to Japanese Patent Application Laid-open (JP-A) No. 2022-030301). According to the bitmap shift method, pixels of a plurality of bitmaps are shifted to be partially overlapped with each other so as to perform writing, thereby reducing gray level errors. However, there is a problem that since a deviation occurs between design positions of pixels of a plurality of bitmaps and actual beam irradiation positions, a desired reduction effect against gray level errors cannot be acquired.

### BRIEF SUMMARY OF THE INVENTION

According to one aspect of the present invention, a multi-charged particle beam writing method includes generating bitmap data defining values each depending on a dose of each pixel of a plurality of pixels, for each of a plurality of writing regions, on a target object, each of which is composed of meshed-divided regions being the plurality of pixels and which are offset from each other by a size equal to or smaller than a size of the each pixel, and performing writing, based on two or more bitmap data in a plurality of bitmap data, to pixels each being in a different one of writing regions each corresponding to one of the two or more bitmap data with a plurality of shots of a same beam in multiple charged particle beams during one tracking control, while repeating a cycle of resetting a deflection amount after each tracking control for deflecting the multiple charged particle beams in order to follow a movement of a stage on which the target object is placed.

According to another aspect of the present invention, a non-transitory computer-readable storage medium storing a program for causing a computer to execute processing, includes
generating a plurality of bitmap data defining values each depending on a dose of each pixel of a plurality of pixels, for a plurality of writing regions, on a target object, each of which is composed of meshed-divided regions being the plurality of pixels and which are offset from each other by a size equal to or smaller than a size of the each pixel,
storing a plurality of bitmap data having been generated in a storage device, and
reading the plurality of bitmap data from the storage device, and controlling, based on two or more bitmap data in the plurality of bitmap data, a writing mechanism to perform writing to pixels each being in a different one of writing regions each corresponding to one of the two or more bitmap data with a plurality of shots of a same beam in multiple charged particle beams during one tracking control, while repeating a cycle of resetting a deflection amount after each tracking control for deflecting the multiple charged particle beams in order to follow a movement of a stage on which the target object is placed.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram for explaining an example of a writing operation according to the first embodiment;

FIG. 5 is a flowchart showing an example of main steps of the writing method according to the first embodiment;

FIG. 6 is an illustration showing an example of a plurality of bitmaps according to the first embodiment;

FIG. 7 is an illustration showing an example of a writing sequence according to the first embodiment;

FIG. 8 is an illustration showing an example of a plurality of bitmaps according to a modified example 1 of the first embodiment;

FIG. 9 is an illustration showing a part of an example of a writing sequence according to the modified example 1 of the first embodiment;

FIG. 10 is an illustration showing the other part of the example of the writing sequence according to the modified example 1 of the first embodiment;

FIG. 11 is an illustration showing an example of a plurality of bitmaps according to a modified example 2 of the first embodiment;

FIG. 12 is an illustration explaining a writing pass according to the modified example 2 of the first embodiment;

FIG. 13 is an illustration showing an example of a writing sequence of the first pass according to the modified example 2 of the first embodiment;

FIG. 14 is an illustration showing an example of a writing sequence of the second pass according to the modified example 2 of the first embodiment;

FIG. 15 is an illustration showing a part of an example of a writing sequence according to a modified example 3 of the first embodiment;

FIG. 16 is an illustration showing the other part of the example of the writing sequence according to the modified example 3 of the first embodiment;

FIG. 17 is an illustration showing another example of a plurality of bitmaps according to the first embodiment;

FIG. 18 is an illustration showing an example of a relationship between a dose and a position when a bitmap is shifted according to the first embodiment; and

FIG. 19 is a graph showing an example of a relationship between an edge deviation amount and a position according to the first embodiment.

### DETAILED DESCRIPTION OF THE INVENTION

Embodiments of the present invention provide a method which can reduce a deviation occurring between the design position of a pixel and the irradiation position of an actual beam in multiple beam writing employing the bitmap shift method.

Embodiments of the present invention describe a configuration in which an electron beam is used as an example of a charged particle beam. The charged particle beam is not limited to the electron beam, and other charged particle beams such as an ion beam may also be used.

### First Embodiment

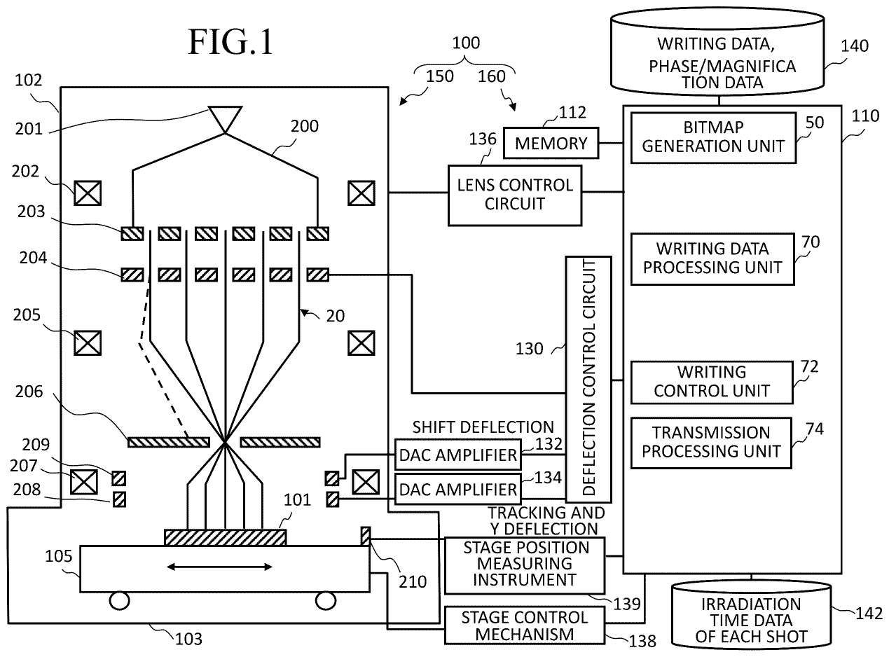

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. In the electron optical column 102, there are disposed an electron source 201, an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101, such as a mask, serving as a writing target substrate when writing (exposure) is performed. For example, the target object 101 is an exposure mask used in fabricating semiconductor devices, or a semiconductor substrate (silicon wafer) for fabricating semiconductor devices. The target object 101 may be a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, digital-analog converter (DAC) amplifier units 132 and 134, a lens control circuit 136, a stage control mechanism 138, a stage position measuring instrument 139, and storage devices 140 and 142 such as magnetic disk drives. The control computer 110, the memory 112, the deflection control circuit 130, the lens control circuit 136, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier 132 disposed for each electrode. The main deflector 208 is composed of at least four electrodes (or “at least four poles”), and controlled by the deflection control circuit 130 through the DAC amplifier 134 disposed for each electrode. Lenses, such as the illumination lens 202, the reducing lens 205, and the objective lens 207 are controlled by the lens control circuit 136.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a bitmap generation unit 50, a writing data processing unit 70, a writing control unit 72, and a transmission processing unit 74. Each of the “ . . . units” such as the bitmap generation unit 50, the writing data processing unit 70, the writing control unit 72, and the transmission processing unit 74 includes processing circuitry. The processing circuitry includes, for example, an electric circuit, computer, processor, circuit board, quantum circuit, semiconductor device, or the like. Each “ . . . unit” may use common processing circuitry (the same processing circuitry), or different processing circuitry (separate processing circuitry). Information input/output to/from the bitmap generation unit 50, the writing data processing unit 70, the writing control unit 72, and the transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns which configure a chip pattern. Specifically, for example, a figure code, coordinates, a size, and the like are defined for each figure pattern.

FIG. 1 shows a configuration necessary for describing the first embodiment. Other configuration elements generally necessary for the writing apparatus 100 may also be included therein.

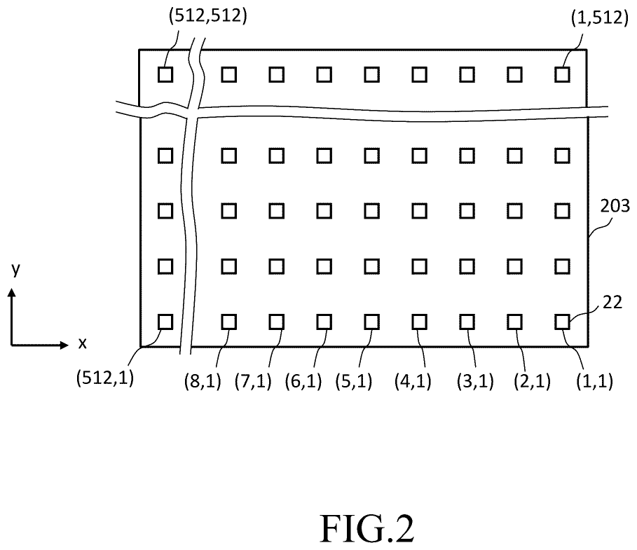

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined array pitch in the shaping aperture array substrate 203. In the case of FIG. 2, for example, holes 22 of 512×512, that is 512 holes in the x direction and 512 holes in the y direction, are formed. The number of the holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. Multiple beams 20 are formed by letting portions of an electron beam 200 individually pass through a corresponding one of a plurality of holes 22. In other words, the shaping aperture array substrate 203 forms the multiple beams 20.

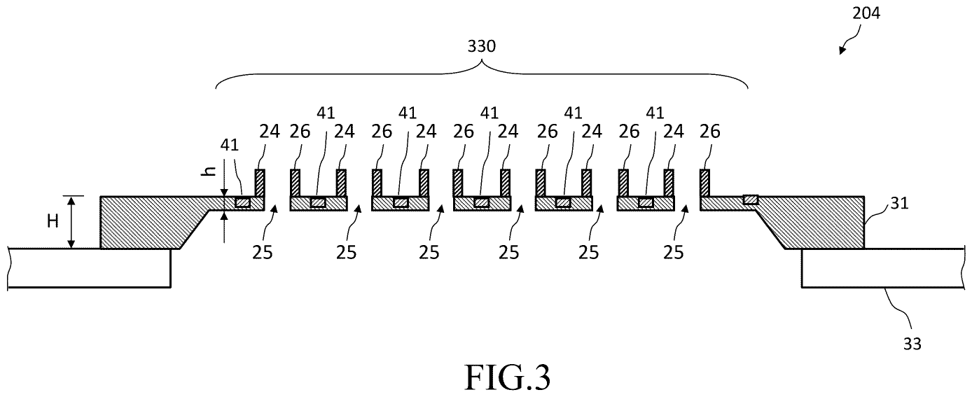

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam-off condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam-on condition by passing through the limiting aperture substrate 206. Blanking control is provided by such deflection.

Next, operations of the writing mechanism 150 will be described. The electron beam 200 emitted from the electron source 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam-on to becoming beam-off and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at a pitch obtained by multiplying the array pitch of a plurality of holes 22 in the shaping aperture array substrate 203 by the desired reduction ratio described above.

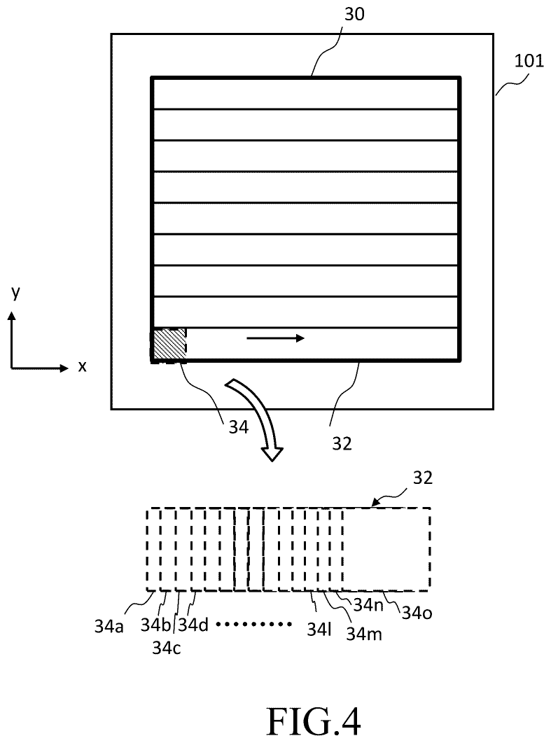

FIG. 4 is a conceptual diagram for explaining an example of a writing operation according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

In the example of FIG. 4, there is set a stripe layer composed of a plurality of stripe regions 32 obtained by dividing the writing region 30.

An example of the writing operation will be described. First, the XY stage 105 is moved to make an adjustment such that the irradiation region 34 of the multiple beams 20 is located at the left end, or at a position further left than the left end, of the first stripe region 32. Then, writing is performed to the first stripe region 32. When writing to the first stripe region 32, the XY stage 105 is moved, for example, in the −x direction, so that the writing may proceed relatively in the x direction. The XY stage 105 is moved, for example, continuously at a constant speed. After writing in the first stripe region 32, the stage position is moved in the-y direction by the shift amount being the width of the stripe region 32. Thereby, the stripe region 32 to be written is shifted in the y direction by the width of the stripe region 32.

Next, an adjustment is made so that the irradiation region 34 of the multiple beams 20 can be located at the left end, or at a position further left than the left end, of the second stripe region 32. Then, by moving the XY stage 105 in the −x direction, for example, writing proceeds relatively in the x direction. Thereby, writing is performed to the second stripe region 32. Thereafter, the writing proceeds in the same way. Thus, writing is performed to the k-th stripe region 32 during one movement in the −x direction of the XY stage 105.

Furthermore, writing processing proceeds while gradually moving the irradiation region 34 (34a to 34o) as shown in the lower part of FIG. 4 by repeating the cycle of the tracking control described above and the tracking reset which resets the deflection amount after deflecting a beam by a tracking control. A specified number of shots by each beam are applied to a plurality of pixels in the sub-irradiation region surrounded by the beam pitch size in the x and y directions on the surface of the target object 101. For example, each sub-irradiation region surrounded by the beam pitch size of the multiple beams 20 applied onto the target object 101 is assumed composed of 4×4 (=16 ) pixels. Then, for example, it is assumed that while four shots are applied during one tracking control, the XY stage makes a movement of eight beam pitches. In that case, in each sub-irradiation region surrounded by the beam pitch size, writing is performed per four pixels during one tracking control. Then, during the next tracking control after resetting the tracking, four pixels in the same sub-irradiation region are to be written with another beam which is distant by eight beams in the x direction, for example. Thus, by performing the tracking control four times, single writing (multiplicity of 1) to all the pixels in each sub-irradiation region is completed with four different beams. Therefore, single writing is performed to the target object 101 with 32(=4×8) beams arranged in the x direction in each of the rows which are arrayed in the y direction. In the case where the multiple beams 20 is composed of, for example, 64 beams arranged in the x direction, multiple writing with a multiplicity of 2 can be performed by the writing method described above. By arranging more beams in the x direction, the multiplicity can further be increased.

Alternatively, using multiple beams necessary for single writing processing, multiple writing can similarly be performed by moving the XY stage 105 a plurality of times to repeat writing to the same stripe region 32.

In a comparative example to the first embodiment, multiple writing is performed by the bit map shift method in which a plurality of bitmaps (for example, two bitmaps) are generated by shifting (offsetting) the reference position of the stripe layer by the size smaller than the pixel size, (e.g., ½ of the pixel), for example. According to the bitmap shift method, by writing to pixels whose relative positions are the same (hereafter, described as “the same pixels”) in a plurality of bitmaps by partially overlapping the pixels with each other, gray level errors occurring in the pixels are reduced. When performing multiple writing, for example, if writing is executed, in the first writing processing, based on a bitmap which has not been shifted, and executed, in the second writing processing, based on a shifted bitmap, gray level errors are supposed to be reduced. However, a deviation occurs between design positions of pixels of a plurality of bitmaps and actual beam irradiation positions, which brings a problem that a desired reduction effect against gray level errors cannot be acquired.

As a cause of this problem, deviation of a tracking deflection and/or distortion of a beam array shape of the multiple beams 20 can be cited. Regarding the main deflector 208 used for tracking control with a large amount of deflection, deflection errors are easy to generate if the deflection timing differs. Therefore, when multiple writing is performed to the same pixel by tracking controls of different timings, positional deviation is easily generated. Furthermore, due to manufacturing errors of the beam-forming hole 22 and optical errors, the irradiation position of each beam deviates. Therefore, distortion may be generated in the beam array shape of the multiple beams 20. Accordingly, when multiple writing is performed to the same pixel with different beams, especially with beams which are distant from each other, positional deviation may easily occur.

Then, according to the first embodiment, each pixel is multiply written, based on the bitmap shift method, by the same beam and during the same tracking control. It is specifically described below.

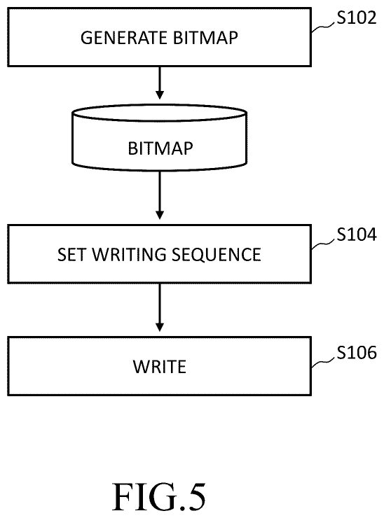

FIG. 5 is a flowchart showing an example of main steps of the writing method according to the first embodiment. In FIG. 5, the writing method of the first embodiment executes a series of steps: a bitmap generation step (S102), a writing sequence setting step (S104), and a writing step (S106).

In the bitmap generation step (S102), first, the writing data processing unit 70 calculates, for each pixel 36, a dose D with which the pixel 36 concerned is irradiated. For example, the dose D can be calculated by multiplying a preset base dose D_{base}, a proximity effect correction irradiation coefficient Dₚ, and a pattern area density ρ. Thus, it is preferable to obtain the dose D to be in proportion to a pattern area density calculated for each pixel 36. For obtaining a proximity effect correction irradiation coefficient Dₚ, first, the writing region (e.g., in this case, stripe region 32) is virtually divided into a plurality of proximity mesh regions (mesh regions for proximity effect correction calculation) by a predetermined size. The size of the proximity mesh region is preferably set to be about 1/10 of the influence range of the proximity effect, such as about 1 μm. Then, writing data is read from the storage device 140, and, for each proximity mesh region, a pattern density ρ′ of a pattern arranged in the proximity mesh region concerned is calculated.

Next, for each proximity mesh region, a proximity effect correction irradiation coefficient Dₚ for correcting a proximity effect is calculated. Here, the size of the mesh region to calculate the proximity effect correction irradiation coefficient Dₚ does not need to be the same as that of the mesh region to calculate a pattern density ρ′. The correction model of the proximity effect correction irradiation coefficient Dₚ and its calculation method may be the same as those used in the conventional single beam writing system.

The writing data processing unit 70 calculates, for each pixel 36, an irradiation time “t” of an electron beam for applying a calculated dose D to the pixel 36 concerned. The irradiation time “t” can be obtained by dividing the dose D by a current density J. Thereby, a dose map (actually, an irradiation time map) for each pixel 36 is generated.

The bitmap generation unit 50 generates bitmap data defining values each depending on the dose of each pixel, for a plurality of stripe regions 32 (an example of a writing region) of the target object 101, each of which is composed of divided mesh regions being a plurality of pixels 36 and whose positions are offset from each other by the size equal to or smaller than that of the pixel 36. That is, the bitmap generation unit 50 generates a plurality of bitmap data (dose map) defining values each depending on the dose D (dose amount) of each pixel 36 (dose), for a plurality of stripe regions 32 (an example of a writing region) of the target object 101 each of which is composed of a plurality of mesh-like pixels 36 and whose positions are shifted from each other by the size smaller than or equal to that of the pixel 36. For each pixel being an element of the bitmap (dose map) indicated by each bitmap data, data (irradiation time data) showing an irradiation time, for example, is defined as a value depending on the dose D (dose).

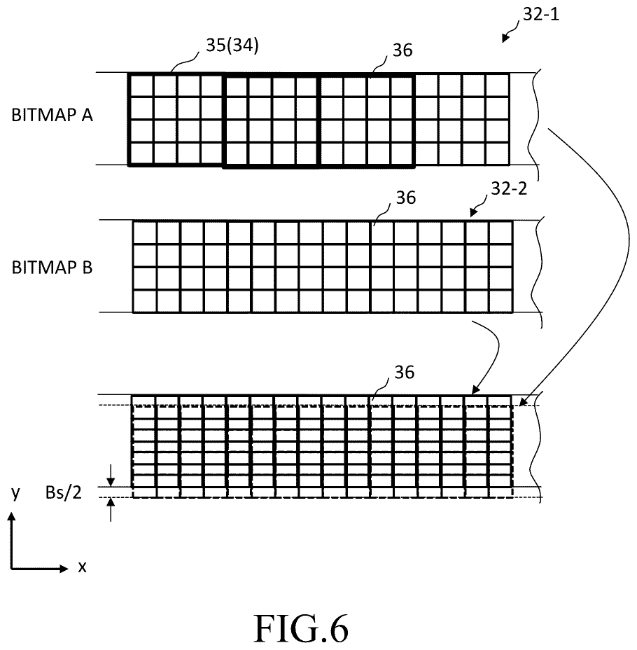

FIG. 6 is an illustration showing an example of a plurality of bitmaps according to the first embodiment. In the first embodiment, a plurality of writing regions are divided in the direction linearly independent of the movement direction of the XY stage 105 so as to include a plurality of stripe regions mutually offset by the size equal to or smaller than that of the pixel region. It will be specifically described. As shown in FIG. 6, the first stripe layer, and the second stripe layer which is shifted, for example, in the y direction from the first stripe layer by the size smaller than or equal to the pixel 36 are formed in the writing region 30. The first stripe layer is composed of a plurality of stripe regions 32-1 obtained by dividing the writing region 30 by a predetermined width in the y direction. The second stripe layer is composed of a plurality of stripe regions 32-2 obtained by dividing the writing region 30 by a predetermined width in the y direction. Thus, the k-th stripe region 32-1 and the k-th stripe region 32-2 are shifted from each other in the y direction by, for example, the size smaller than or equal to that of the pixel 36. In the case of FIG. 6, the stripe region 32-2 is set to be shifted in the y direction from the stripe region 32-1 by ½ of the size of the pixel 36, (in FIG. 6, the size of the pixel 36 is shown as “beam size Bs”. The same applies below.) Therefore, if overlapping the stripe region 32-1 and the stripe region 32-2 each other, pixels at the same position in the two stripe regions 32-1 and 32-2 are partially overlapped with each other. In FIG. 6, regions each being ½ of the pixel are overlapped with each other in the y direction with respect to the stripe regions.

Since the number of times of multiple writing changes according to the number of bitmaps, a value obtained by dividing a dose D (irradiation time) concerned by the number of times of multiple writing is defined, in each bitmap, as the dose D (irradiation time) of each pixel 36. For example, in general, in the case of generating n bitmaps per writing processing in multiple writing with a multiplicity of N, since the number of times of the multiple writing is Nn, a value being 1/Nn of an acquired dose D (irradiation time) of each pixel is defined for the corresponding pixel in each bitmap.

In the writing sequence setting step (S104), the writing control unit 72 sets a writing sequence.

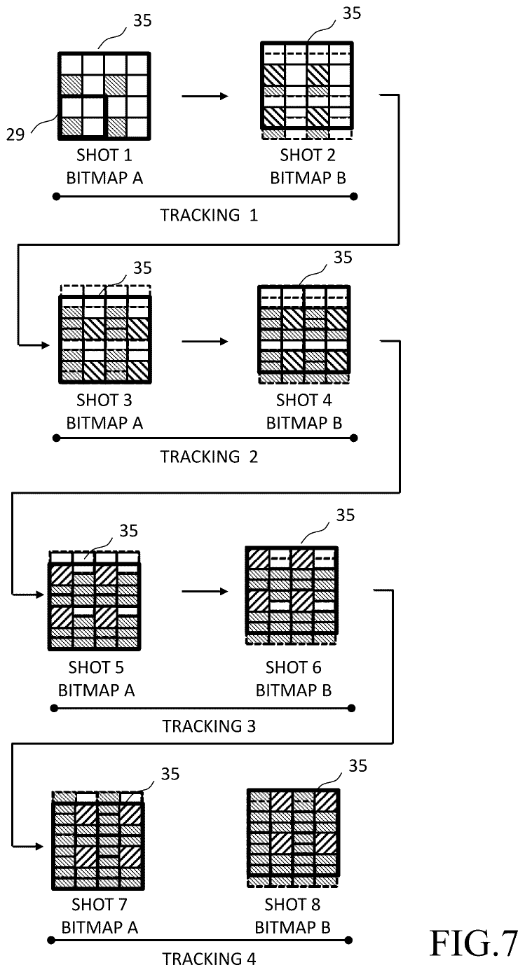

FIG. 7 is an illustration showing an example of a writing sequence according to the first embodiment. FIG. 7 shows the case of using 2×2 multiple beams 20, for example. In the example of FIG. 7, a sub-irradiation region 29 surrounded by the beam pitch sizes on the surface of the target object 101 is composed of 2×2 pixels 36. Each of the stripe regions 32-1 and 32-2 can be divided into a plurality of rectangular regions 35 each having the same size as the irradiation region 34. The same writing processing is repeated for each rectangular region 35. Since the rectangular region 35 is the same size as the irradiation region 34, each rectangular region 35 includes 4×4 pixels 36. FIG. 7 shows the case where, for example, two shots of multiple beams 20 are applied during one tracking control. The XY stage 105 moves m beam pitches (for example, one beam pitch) during one tracking control.

According to the writing sequence of the first embodiment, the bitmap is interchanged per shot during the same tracking control. FIG. 7 shows the case, during each tracking control, the bitmap A is used first, and then the bitmap B is used. The order of bitmaps is not limited thereto. Instead of the order of A, B, A, B, . . . A, B, the order of A, B, B, A, A, B, and so on may also be used, for example. What is important is to interchange, for example, every bitmap during each tracking control.

In each sub-irradiation region 29, the sequence of writing to each pixel is set to be in the order of the pixels at the lower left, the lower right, the upper left, and the upper right, for example. The order of writing pixels is not limited thereto. As the writing order of 2×2 pixels, another one such as from the upper left, the upper right, the lower left, and the lower right may also be sufficient, for example.

In the writing step (S106), first, the writing data processing unit 70 rearranges irradiation time data to be in the order of shots, based on the writing sequence having been set. The irradiation time data is stored in the storage device 142. The transmission processing unit 74 reads irradiation time data, in the order of shots, from the storage device 142, and transmits it to the deflection control circuit 130.

After tracking control for deflecting the multiple beams 20 in order to follow the movement of the XY stage 105 with the target object 101 thereon, while repeating the cycle of resetting the deflection amount, the writing mechanism 150 performs writing to the pixels 36, each being in a different one of the stripe regions 32-1 and 32-2 each corresponding to one of two or more bitmap data A and B, with a plurality of shots of the same beam in the multiple beams 20, during one tracking control, based on two or more bitmap data A and B in a plurality of bitmap data. In other words, based on data of a plurality of bitmaps A and B, the writing mechanism 150 performs writing to the pixels 36 in two or more stripe regions 32-1 and 32-2 indicated by the data of two or more bitmaps A and B in data of a plurality of bitmaps A and B, with a plurality of shots of the same beam in the multiple beams 20, during the same tracking control in a plurality of tracking controls which deflect beams of the multiple beams 20 to follow the movement of the XY stage 105 with the target object 101 thereon. According to the first embodiment, in the writing step (S106), writing to the same pixels 36 each being in a different one of the stripe regions 32-1 and 32-2 each corresponding to two or more bitmap data is performed during one tracking control. In other words, according to the first embodiment, during each tracking control, the writing mechanism 150 performs writing to the same pixels 36 in stripe regions shown by a plurality of bitmaps with a plurality of shots of the same beam of the multiple beams 20. For example, in the case of FIG. 7, during each tracking control, the writing mechanism 150 performs writing to the same pixels 36 in the stripe regions 32-1 and 32-2 shown by the two bitmaps A and B with two shots of the same beam of the multiple beams 20.

Specifically, it operates as described below. As shown in FIG. 7, during the first tracking control, the shot 1 applies a beam to the pixel at the lower left of each sub-irradiation region 29, using the bitmap A, and the shot 2 applies the same beam as that of the shot 1 to the same pixel 36, using the bitmap B. The shot position of the multiple beams 20 of each shot during each tracking control is adjusted by beam deflection by the sub deflector 209. After these two shots, tracking is reset.

Similarly, during the second tracking control, the shot 3 applies a beam to the pixel at the lower right of each sub-irradiation region 29, using the bitmap A, and the shot 4 applies the same beam as that of the shot 3, (which is a beam different from those of the shots 1 and 2), to the same pixel 36, using the bitmap B. After these two shots, tracking is reset.

Similarly, during the third tracking control, the shot 5 applies a beam to the pixel at the upper left of each sub-irradiation region 29, using the bitmap A, and the shot 6 applies the same beam as that of the shot 5, (which is a beam different from those of the shots 1 to 4), to the same pixel 36, using the bitmap B. After these two shots, tracking is reset.

Similarly, during the fourth tracking control, the shot 7 applies a beam to the pixel at the upper right of each sub-irradiation region 29, using the bitmap A, and the shot 8 applies the same beam as that of the shot 7, (which is a beam different from those of the shots 1 to 6), to the same pixel 36, using the bitmap B. After these two shots, tracking is reset.

As a result of the above-described, writing to all the pixels 36 in the rectangular region 35 is completed. By proceeding the writing process similarly, the whole of the stripe regions 32-1 and 32-2 can be written. By similarly writing to the stripe region of each row, the whole of the writing region 30 of the target object 101 is completely written.

According to the first embodiment, since writing to the same pixel 36 of each bitmap is performed with the same beam during the same tracking control, the influence of tracking deflection errors and of beam array distortion can be eliminated or reduced. Therefore, gray level errors can be reduced.

Next, a modified example 1 of the first embodiment is described. In the bitmap generation step (S102) of the modified example 1, the bitmap generation unit 50 generates data of two bitmaps (dose maps) A and B that define values each depending on the dose D (dose amount) for each pixel 36 in a plurality of stripe regions 32, on the target object 101, shifted from each other by ½ of the size of the pixel 36.

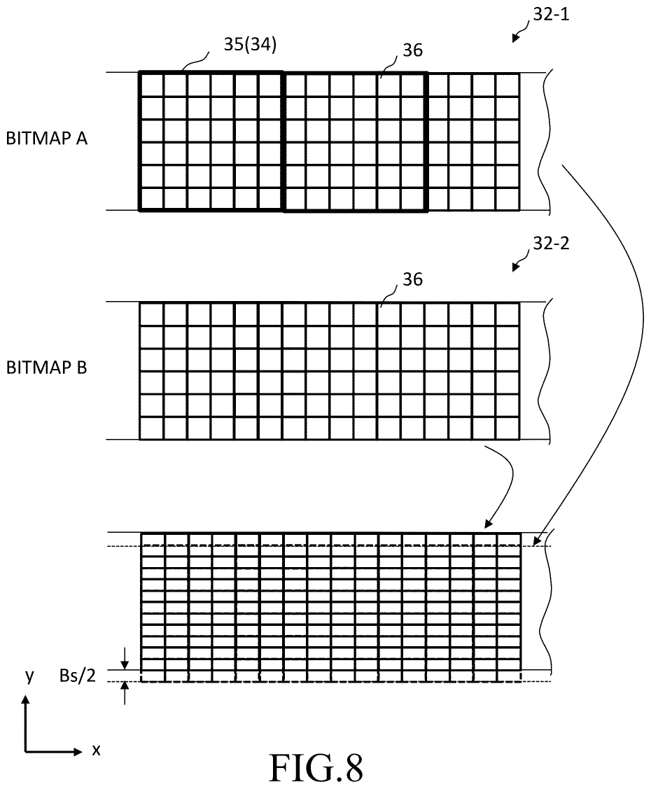

FIG. 8 is an illustration showing an example of a plurality of bitmaps according to the modified example 1 of the first embodiment. As shown in FIG. 8, in the writing region 30, the first stripe layer and the second stripe layer shifted, for example, in the y direction from the first stripe layer by the size smaller than or equal to the pixel 36 are formed. FIG. 8 shows the case where the rectangular region 35 is composed of 6×6(=36) pixels. In the case of FIG. 8, the stripe region 32-2 is set to be shifted in the y direction from the stripe region 32-1 by ½ of the size Bs of the pixel 36. In FIG. 8, regions each being ½ of the pixel are overlapped with each other in the y direction with respect to the stripe regions. The other respects in FIG. 8 are the same as those of FIG. 6.

In the writing sequence setting step (S104) of the modified example 1, the writing control unit 72 sets a writing sequence.

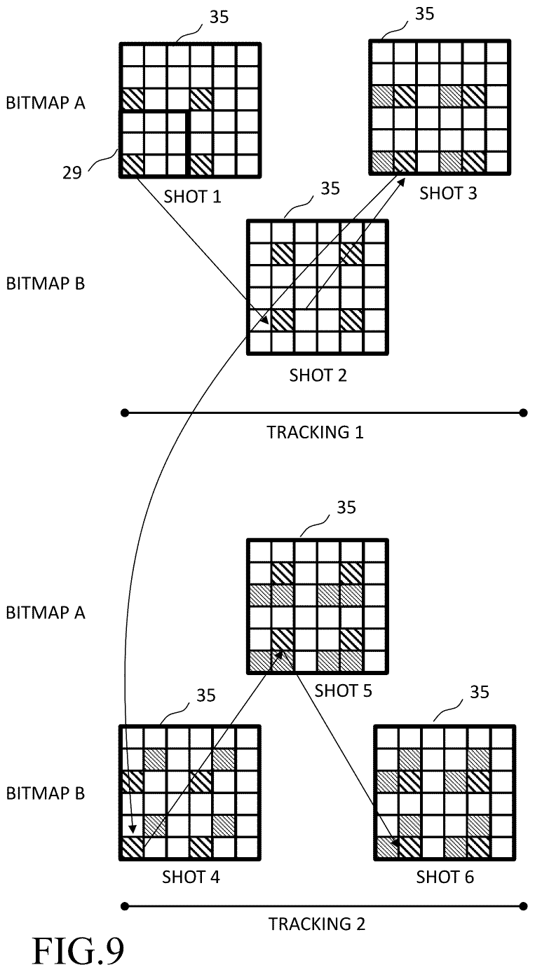

FIG. 9 is an illustration showing a part of an example of a writing sequence according to the modified example 1 of the first embodiment.

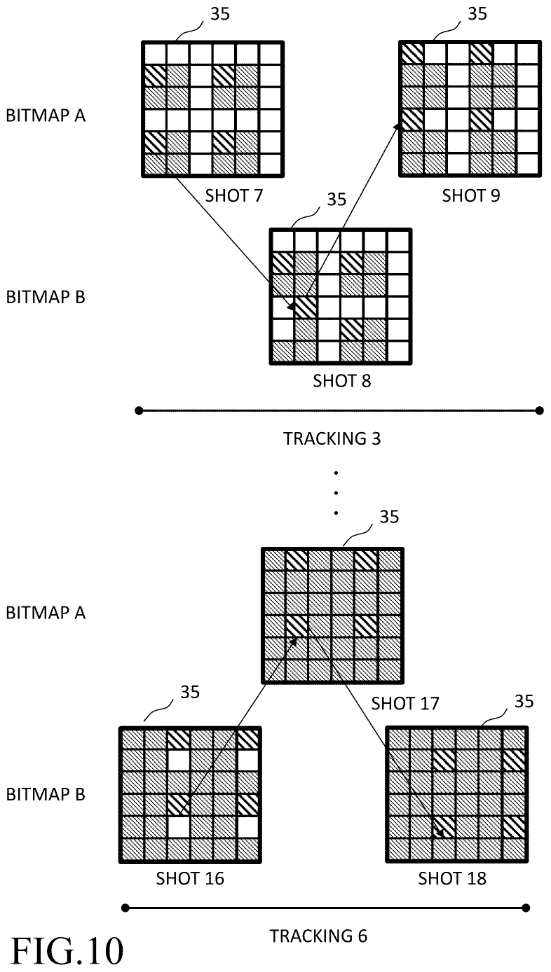

FIG. 10 is an illustration showing the other part of the example of the writing sequence according to the modified example 1 of the first embodiment.

In the examples of FIGS. 9 and 10, 2×2 multiple beams 20 are used, for example. FIGS. 9 and 10 show the case where the sub-irradiation region 29 surrounded by the beam pitch size on the surface of the target object 101 is composed of 3×3 pixels 36. Each of the stripe regions 32-1 and 32-2 is divided into a plurality of rectangular regions 35 each having the same size as the irradiation region 34. Therefore, 6×6 pixels 36 are included in each rectangular region 35. FIGS. 9 and 10 show the case where three shots of the multiple beams 20 are applied during one tracking control, for example. The XY stages 105 moves the distance of one beam pitch during one tracking control, for example.

According to the writing sequence of the first embodiment, the bitmap is interchanged for each shot during the same tracking control. In the case of FIG. 9, during the first tracking control, the bitmap A is used first, then the bitmap B is used, and, finally the bitmap A is used. During the second tracking control, the bitmap B is used first, then the bitmap A is used, and, finally the bitmap B is used. Thereafter, it is repeated similarly. The order of the bitmaps is not limited thereto. For example, instead of the order of A, B, A, B, A, B, it may be A, B, B, A, A, B, and so on.

In each sub-irradiation region 29, with respect to the bitmap A, the writing sequence of writing to each pixel is set as follows: In the order of the pixels at the first from the left in the first row from the bottom, the second from the left in the first row from the bottom, the second from the left in the second row from the bottom, the first from the left in the second row from the bottom, the first from the left in the third row from the bottom, the third from the left in the first row from the bottom, the third from the left in the third row from the bottom, the third from the left in the second row from the bottom, and the second from the left in the third row from the bottom. With respect to the bitmap B, the writing sequence of writing to each pixel is set as follows: In the order of the pixels at the second from the left in the second row from the bottom, the first from the left in the first row from the bottom, the second from the left in the first row from the bottom, the second from the left in the third row from the bottom, the first from the left in the second row from the bottom, the first from the left in the third row from the bottom, the third from the left in the first row from the bottom, the third from the left in the third row from the bottom, and the third from the left in the second row from the bottom. However, the order of pixels to be written is not limited thereto. In each bitmap, another order is acceptable for 3×3 pixels.

In the writing step (S106) of the modified example 1, first, the writing data processing unit 70 interchanges irradiation time data, in the order of shots, based on the writing sequence having been set. The irradiation time data is stored in the storage device 142. Then, the transmission processing unit 74 reads irradiation time data, in the order of shots, from the storage device 142, and transmits it to the deflection control circuit 130.

According to the modified example 1 of the first embodiment, in the writing step, writing of different pixels 36, each being in a different one of the stripe regions 32-1 and 32-2 each corresponding to two or more bitmap data is performed during one tracking control. In other words, during each tracking control, the writing mechanism 150 performs writing to different pixels 36 (in terms of relative positions) in stripe regions shown by a plurality of bitmaps with a plurality of shots of the same beam of the multiple beams 20. For example, in the cases of FIGS. 9 and 10, during each tracking control, the writing mechanism 150 performs writing to different pixels 36 in the stripe regions 32-1 and 32-2 shown by the two bitmaps A and B with three shots of the same beam of the multiple beams 20.

Specifically, it operates as described below. As shown in FIG. 9, during the first tracking control, the shot 1 applies a beam to the first pixel from the left in the first row from the bottom of each sub-irradiation region 29, using the bitmap A, the shot 2 applies the same beam as that of the shot 1 to the second pixel from the left in the second row from the bottom of each sub-irradiation region 29, using the bitmap B, and the shot 3 applies the same beam as those of the shots 1 and 2 to the second pixel from the left in the first row from the bottom of each sub-irradiation region 29, using the bitmap A. The shot position of the multiple beams 20 of each shot during each tracking control is adjusted by beam deflection by the sub deflector 209. After these three shots, tracking is reset.

Similarly, during the second tracking control, the shot 4 applies a beam adjacent to the beam of the shot 3 to the first pixel from the left in the first row from the bottom of each sub-irradiation region 29, using the bitmap B, the shot 5 applies the same beam as that of the shot 4 to the second pixel 36 from the left in the second row from the bottom, using the bitmap A, and the shot 6 applies the same beam as those of the shots 4 and 5 to the second pixel 36 from the left in the first row from the bottom, using the bitmap B. After these three shots, tracking is reset.

Similarly, during the third tracking control, the shot 7 applies a beam adjacent to the beam of the shot 6 to the first pixel from the left in the second row from the bottom of each sub-irradiation region 29, using the bitmap A, the shot 8 applies the same beam as that of the shot 7 to the second pixel 36 from the left in the third row from the bottom, using the bitmap B, and the shot 9 applies the same beam as those of the shots 7 and 8 to the first pixel 36 from the left in the third row from the bottom, using the bitmap A. After these three shots, tracking is reset.

Similarly, during the fourth tracking control, the shot 10 applies a beam adjacent to the beam of the shot 9 to the first pixel from the left in the second row from the bottom of each sub-irradiation region 29, using the bitmap B, the shot 11 applies the same beam as that of the shot 10 to the third pixel 36 from the left in the first row from the bottom, using the bitmap A, and the shot 12 applies the same beam as those of the shots 10 and 11 to the first pixel 36 from the left in the third row from the bottom, using the bitmap B. After these three shots, tracking is reset.

Similarly, during the fifth tracking control, the shot 13 applies a beam adjacent to the beam of the shot 12 to the third pixel from the left in the third row from the bottom of each sub-irradiation region 29, using the bitmap A, the shot 14 applies the same beam as that of the shot 13 to the third pixel 36 from the left in the first row from the bottom, using the bitmap B, and the shot 15 applies the same beam as those of the shots 13 and 14 to the third pixel 36 from the left in the second row from the bottom, using the bitmap A. After these three shots, tracking is reset.

Similarly, during the sixth tracking control, the shot 16 applies a beam adjacent to the beam of the shot 15 to the third pixel from the left in the third row from the bottom of each sub-irradiation region 29, using the bitmap B, the shot 17 applies the same beam as that of the shot 16 to the second pixel 36 from the left in the third row from the bottom, using the bitmap A, and the shot 18 applies the same beam as those of the shots 16 and 17 to the third pixel 36 from the left in the second row from the bottom, using the bitmap B. After these three shots, tracking is reset.

As a result of the above-described, writing to all the pixels 36 in the rectangular region 35 is completed. By writing similarly, the whole of the stripe regions 32-1 and 32-2 can be written. By similarly writing to the stripe region of each row, writing to the whole of the writing region 30 of the target object 101 is completed.

According to the modified example 1 of the first embodiment, since the same pixel 36 in each bitmap is written with a beam adjacent to the current beam during a tracking control performed subsequent to the current one, the influence of tracking deflection errors and of beam array distortion can be reduced.

Therefore, gray level errors can be reduced.

Next, a modified example 2 of the first embodiment is described. In the bitmap generation step (S102) of the modified example 2, the bitmap generation unit 50 generates four bitmaps (dose maps) A, B, C, and D that define values each depending on the dose D (dose amount) for each pixel 36 in a plurality of stripe regions 32, on the target object 101, shifted from each other by ¼ of the size of the pixel 36.

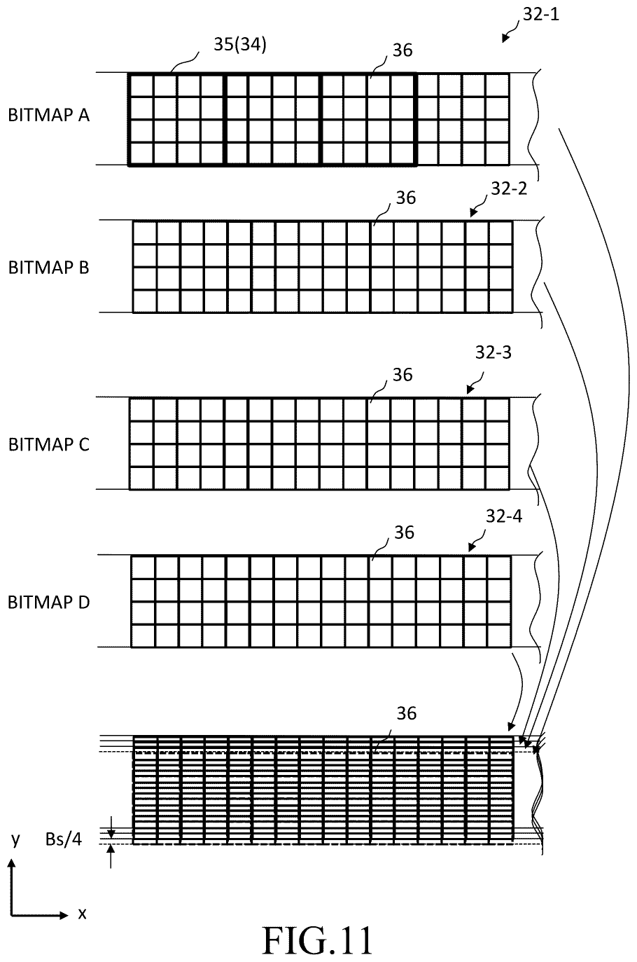

FIG. 11 is an illustration showing an example of a plurality of bitmaps according to the modified example 2 of the first embodiment. As shown in FIG. 11, in the writing region 30, formed are the first stripe layer, the second stripe layer shifted, for example, in the y direction from the first stripe layer by ¼ of the size of the pixel 36, the third stripe layer shifted, for example, in the y direction from the second stripe layer by ¼ of the size of the pixel 36, and the fourth stripe layer shifted, for example, in the y direction from the third stripe layer by ¼ of the size of the pixel 36. FIG. 11 shows the case where the rectangular region 35 is composed of 4×4(=16) pixels. In the case of FIG. 11, the stripe region 32-2 is set to be shifted in the y direction from the stripe region 32-1 by ¼ of the size Bs of the pixel 36. Similarly, the stripe region 32-3 is set to be shifted in the y direction from the stripe region 32-1 by 2/4 of the size Bs of the pixel 36. Similarly, the stripe region 32-4 is set to be shifted in the y direction from the stripe region 32-1 by ¾ of the size Bs of the pixel 36. In FIG. 11, regions each being ¼ of the pixel are overlapped with each other in the y direction with respect to all the bitmaps. The other respects in FIG. 11 are the same as those of FIG. 6.

In the writing sequence setting step (S104) of the modified example 2, the writing control unit 72 sets a writing sequence.

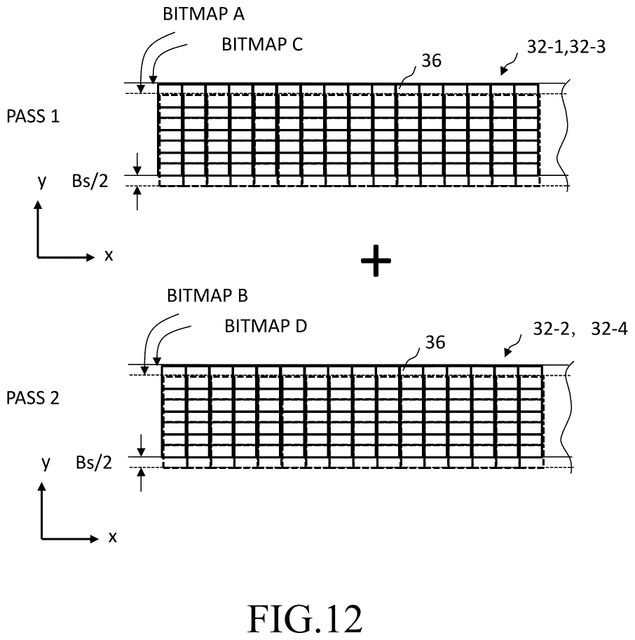

FIG. 12 is an illustration explaining a writing pass according to the modified example 2 of the first embodiment. In the case of FIG. 12, during one movement in the-x direction of the XY stage 105, the k-th stripe region 32-1 of the bitmap A and the k-th stripe region 32-3 of the bitmap C are written (pass 1). Then, the XY stage 105 is returned to the writing starting position of the k-th stripe region in order to repeat the movement. Then, the k-th stripe region 32-2 of the bitmap B and the k-th stripe region 32-4 of the bitmap D are written during one movement in the-x direction of the XY stage 105 (pass 2).

As described above, it is also preferable to divide the four bitmaps into two, and to assign two bitmaps to one stripe pass and the others to another pass.

In the case of FIG. 12, the bitmaps are divided into a group of the bitmaps A and C, and a group of the bitmaps B and D, but it is not limited thereto. For example, they may be divided into a group of the bitmaps A and B, and a group of the bitmaps C and D, or, into a group of A and D, and a group of B and C.

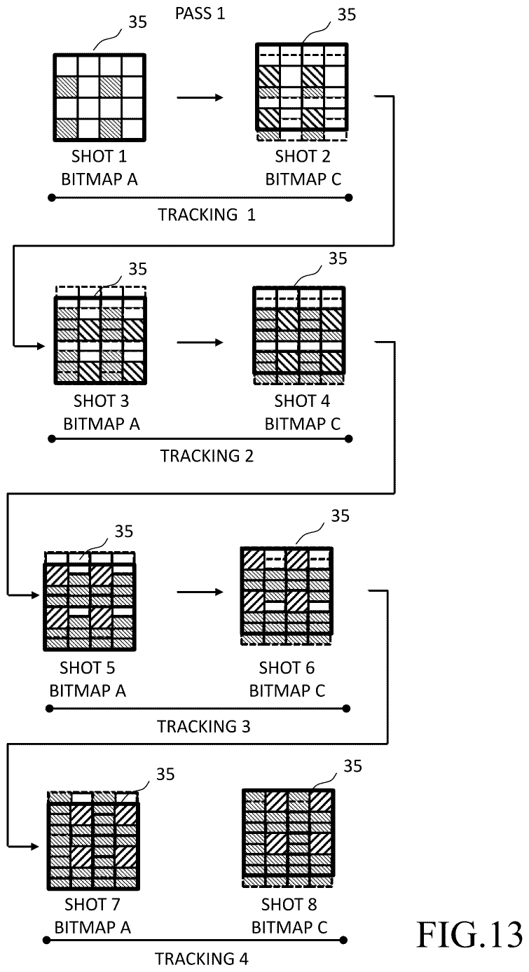

FIG. 13 is an illustration showing an example of a writing sequence of the first pass according to the modified example 2 of the first embodiment.

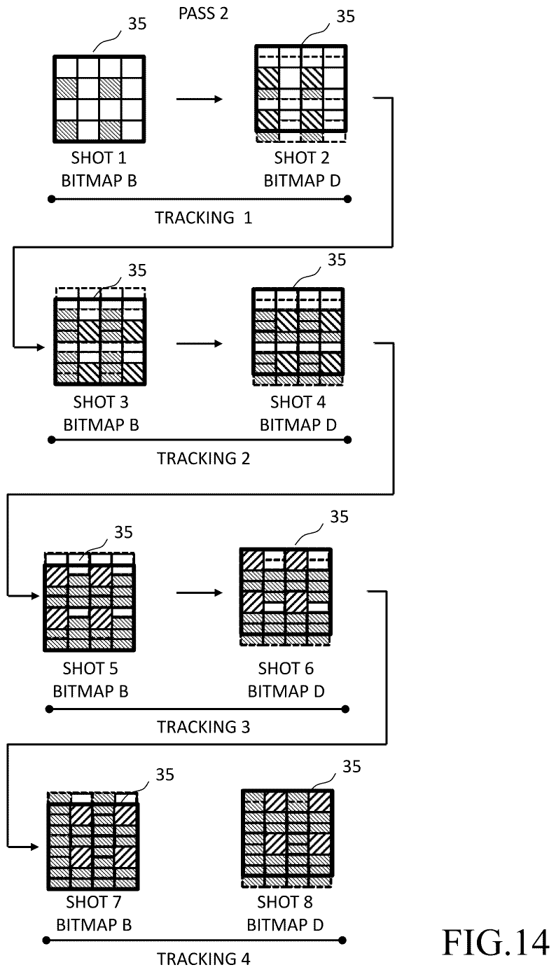

FIG. 14 is an illustration showing an example of a writing sequence of the second pass according to the modified example 2 of the first embodiment.

In the examples of FIGS. 13 and 14, 2×2 multiple beams 20 are used, for example. FIGS. 13 and 14 show the case where the sub-irradiation region 29 surrounded by the beam pitch size on the surface of the target object 101 is composed of 2×2 pixels 36. Each of the stripe regions 32-1, 32-2, 32-3, and 32-4 is divided into a plurality of rectangular regions 35 each having the same size as the irradiation region 34. Therefore, 4×4 pixels 36 are included in each rectangular region 35. FIGS. 13 and 14 show the case where, for example, two shots of the multiple beams 20 are applied during one tracking control. The XY stages 105 moves the distance of m beam pitches (for example, one beam pitch) during one tracking control.

According to the writing sequence of the modified example 2 of the first embodiment, the bitmap is interchanged for each shot during the same tracking control. In the case of FIG. 13, during the first tracking control, the bitmap A is used first, and then, the bitmap C is used. During the second tracking control, the bitmap A is used first, and then, the bitmap C is used. Thereafter, it is repeated similarly. The order of the bitmaps is not limited thereto. For example, instead of the order of A, C, A, C, . . . , it may be A, C, C, A, A, C, and so on. What is important is to interchange, for example, bitmaps A and C during each tracking control.

Similarly, in the case of FIG. 14, in the first tracking control, the bitmap B is used first, and then, the bitmap D is used. In the second tracking control, the bitmap B is used first, and then the bitmap D is used. Thereafter, it is repeated similarly. The order of the bitmaps is not limited thereto. For example, instead of the order of B, D, B, D, . . . , it may be B, D, D, B, B, D, and so on. What is important is to interchange, for example, bitmaps B and D during each tracking control.

In each sub-irradiation region 29, the sequence of writing to each pixel is set to be in the order of the pixels at the lower left, the lower right, the upper left, and the upper right, for example. The order of writing pixels is not limited thereto. As the writing order of 2×2 pixels, another one such as from the upper left, the upper right, the lower left, and the lower right may also be sufficient, for example.

In the writing step (S106) of the modified example 2, first, the writing data processing unit 70 interchanges irradiation time data, in each pass, to be in the order of shots, based on the writing sequence having been set. The irradiation time data is stored in the storage device 142. Then, the transmission processing unit 74 transmits irradiation time data, in the order of shots, from the storage device 142 to the deflection control circuit 130.

Based on data of a plurality of bitmaps A, B, C, and D, the writing mechanism 150 performs writing to the pixels 36 in two or more stripe regions 32-1 and 32-3 (32-2, 32-4) indicated by the data of two or more bitmaps A and C (B, D) in data of a plurality of bitmaps A, B, C and D with a plurality of shots of the same beam in the multiple beams 20, during the same tracking control in a plurality of tracking controls which deflect beams of the multiple beams 20 to follow the movement of the XY stage 105 with the target object 101 thereon.

In other words, according to the modified example 2 of the first embodiment, in the writing step, during the first tracking control being one tracking control, pixels in two or more stripe regions of a plurality of stripe regions are written with the first beam of the multiple beams 20, based on two or more bitmap data, being a portion of bitmap data, of the plurality of bitmap data for the plurality of stripe regions. Then, during the second tracking control, being one tracking control, performed before or after the first tracking control, pixels in another one or more stripe regions of the plurality of stripe regions are written with the first beam, based on another one or more bitmap data, being another portion of the bitmap data, of the plurality of bitmap data for the plurality of stripe regions. Furthermore, the first tracking control and the second tracking control are provided for each writing of at least any one of a plurality of stripe regions.

Said differently, according to the modified example 2 of the first embodiment, during each tracking control, the writing mechanism 150 proceeds the writing processing for the whole of two or more stripe regions 32-1 and the 32-3 by performing writing to the pixels 36 in the two or more stripe regions 32-1 and 32-3 indicated by data of two or more bitmaps A and C, in the data of a plurality of bitmaps A, B, C, and D, with a plurality of shots of the same beam of the multiple beams 20. Furthermore, during each tracking control, the writing mechanism 150 proceeds the writing processing for the whole of one or more stripe regions 32-2 and the 32-4 by performing writing to the pixel(s) 36 in the one or more stripe regions 32-2 and 32-4 indicated by data of one or more bitmaps B and D, in the data of the plurality of bitmaps A, B, C, and D, with one or more shots of the same beam of the multiple beams 20. After one of writing processing for the whole of two or more stripe regions 32-1 and the 32-3, being a part of stripe regions, and writing processing for the whole of one or more stripe regions 32-2 and 32-4, being the other part of the stripe regions, is completed, the other writing processing is performed.

Furthermore, according to the modified example 2 of the first embodiment, during each tracking control, in each pass, the writing mechanism 150 writes to the same pixels 36 in the stripe regions 32-1 and 32-3 (32-2, 32-4) indicated by a plurality of bitmaps, with a plurality of shots of the same beam of the multiple beams 20. In the case of FIG. 13, during each tracking control, in the first pass, the writing mechanism 150 writes to the same pixels 36 in the stripe regions 32-1 and 32-3 indicated by the two bitmaps A and C with two shots of the same beam of the multiple beams 20. In the case of FIG. 14, during each tracking control, in the second pass, the writing mechanism 150 writes to the same pixels 36 in the stripe regions 32-2 and 32-4 indicated by the two bitmaps B and D with two shots of the same beam of the multiple beams 20.

Specifically, it operates as described below. As shown in FIG. 13, during the first tracking control of the first pass, the shot 1 applies a beam to the pixel at the lower left of each sub-irradiation region 29, using the bitmap A, and the shot 2 applies the same beam as that of the shot 1 to the same pixel 36, using the bitmap C. The shot position of the multiple beams 20 of each shot during each tracking control is adjusted by beam deflection by the sub deflector 209. After these two shots, tracking is reset.

Similarly, during the second tracking control of the first pass, the shot 3 applies a beam, which is different from those of the shots 1 and 2, to the pixel at the lower right of each sub-irradiation region 29, using the bitmap A, and the shot 4 applies the same beam as that of the shot 3 to the same pixel 36, using the bitmap C. After these two shots, tracking is reset.

Similarly, during the third tracking control of the first pass, the shot 5 applies a beam, which is different from those of the shots 1 to 4, to the pixel at the upper left of each sub-irradiation region 29, using the bitmap A, and the shot 6 applies the same beam as that of the shot 5 to the same pixel 36, using the bitmap C. After these two shots, tracking is reset.

Similarly, during the fourth tracking control of the first pass, the shot 7 applies a beam, which is different from those of the shots 1 to 6, to the pixel at the upper right of each sub-irradiation region 29, using the bitmap A, and the shot 8 applies the same beam as that of the shot 7 to the same pixel 36, using the bitmap C. After these two shots, tracking is reset.

As a result of the above-described, writing to all the pixels 36 in the rectangular region 35 by the first pass is completed.

Next, as shown in FIG. 14, during the first tracking control of the second pass, the shot 1 applies a beam to the pixel at the lower left of each sub-irradiation region 29, using the bitmap B, and the shot 2 applies the same beam as that of the shot 1 to the same pixel 36, using the bitmap D. The shot position of the multiple beams 20 of each shot during each tracking control is adjusted by beam deflection by the sub deflector 209. After these two shots, tracking is reset.

Similarly, during the second tracking control of the second pass, the shot 3 applies a beam, which is different from those of the shots 1 and 2, to the pixel at the lower right of each sub-irradiation region 29, using the bitmap B, and the shot 4 applies the same beam as that of the shot 3 to the same pixel 36, using the bitmap D. After these two shots, tracking is reset.

Similarly, during the third tracking control of the second pass, the shot 5 applies a beam, which is different from those of the shots 1 to 4, to the pixel at the upper left of each sub-irradiation region 29, using the bitmap B, and the shot 6 applies the same beam as that of the shot 5 to the same pixel 36, using the bitmap D. After these two shots, tracking is reset.

Similarly, during the fourth tracking control of the second pass, the shot 7 applies a beam, which is different from those of the shots 1 to 6, to the pixel at the upper right of each sub-irradiation region 29, using the bitmap B, and the shot 8 applies the same beam as that of the shot 7 to the same pixel 36, using the bitmap D. After these two shots, tracking is reset.

As a result of the above-described, writing to all the pixels 36 in the rectangular region 35 by the second pass is completed. By proceeding the writing process similarly, the whole of the stripe regions 32-1, 32-2, 32-3, and 32-4 can be written. By similarly writing to the stripe region of each row, the whole of the writing region 30 of the target object 101 is completely written.

Although it is preferable, for each stripe region 32, to continuously perform writing (multiple writing with a multiplicity of 2) of the first pass and writing (multiple writing with a multiplicity of 2) of the second pass, which results in multiple writing with a multiplicity of 4, it is not limited thereto. It is also preferable that after completing writing a plurality of stripe regions in the entire writing region 30 by the first pass, a plurality of stripe regions in the entire writing region 30 by the second pass are written.

According to the modified example 2 of the first embodiment, although the same pixels in two of four bitmaps are written by different beams during different tracking periods, the same pixels in the other two bitmaps are written with the same beam during the same tracking control. Therefore, the influence of tracking deflection errors and of beam array distortion can be reduced. Accordingly, gray level errors can be reduced.

Next, a modified example 3 of the first embodiment is described. The bitmap generation step (S102) of the modified example 3 is the same as that of the modified example 2. As shown in FIG. 11, the bitmap generation unit 50 generates four bitmaps (dose maps) A, B, C, and D which are shifted from each other by ¼ of the size of the pixel 36.

In the writing sequence setting step (S104) of the modified example 3, the writing control unit 72 sets a writing sequence.

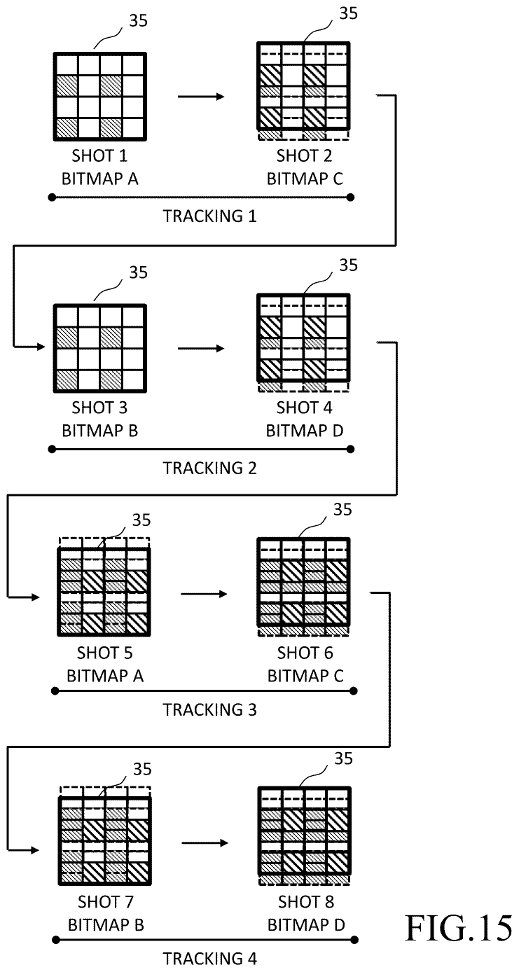

FIG. 15 is an illustration showing a part of an example of a writing sequence according to the modified example 3 of the first embodiment.

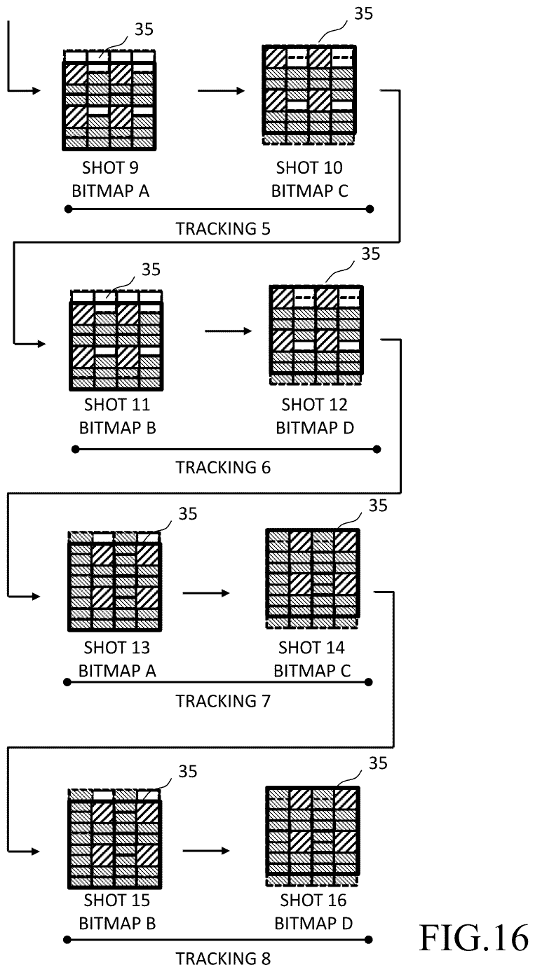

FIG. 16 is an illustration showing the other part of the example of the writing sequence according to the modified example 3 of the first embodiment.

In the examples of FIGS. 15 and 16, 2×2 multiple beams 20 are used, for example. FIGS. 15 and 16 show the case where the sub-irradiation region 29 surrounded by the beam pitch size on the surface of the target object 101 is composed of 2×2 pixels 36. Each of the stripe regions 32-1, 32-2, 32-3, and 32-4 is divided into a plurality of rectangular regions 35 each having the same size as the irradiation region 34. Therefore, 4×4 pixels 36 are included in each rectangular region 35. FIGS. 15 and 16 show the case where two shots of the multiple beams 20 are applied during one tracking control, for example. The XY stages 105 moves the distance of m beam pitches (for example, one beam pitch) during one tracking control.

According to the writing sequence of the modified example 3 of the first embodiment, two or more bitmaps in a plurality of bitmaps are interchanged, for each shot, during the same tracking control. In the cases of FIGS. 15 and 16, during the same tracking control, the bitmaps A and C are interchanged. In addition, during another same tracking control, the bitmaps B and D are interchanged.

In the cases of FIGS. 15 and 16, during the first tracking control, the bitmap A is used first, and then, the bitmap C is used. During the second tracking control, the bitmap B is used first, and then, the bitmap D is used. Thereafter, it is repeated similarly. The order of the bitmaps is not limited thereto. In addition to the order of A, C, B, D, . . . , the order of C, A, B, D, . . . , that of C, A, D, B, . . . , that of B, D, A, C, . . . , that of D, B, A, C, . . . , or that of D, B, C, A, . . . may also be used, for example. What is important is that, during two-times continuous tracking controls, the bitmaps A and C, for example, are interchanged during one tracking control, and the bitmaps B and D, for example, are interchanged during the other.

In the cases of FIGS. 15 and 16, the bitmaps are divided into a group of the bitmaps A and C, and a group of the bitmaps B and D, but it is not limited thereto. For example, they may be divided into a group of the bitmaps A and B, and a group of the bitmaps C and D, or, into a group of A and D, and a group of B and C.

In each sub-irradiation region 29, the sequence of writing to each pixel is set to be in the order of the pixels at the lower left, the lower right, the upper left, and the upper right, for example. The order of writing pixels is not limited thereto. As the writing order of 2×2 pixels, another one such as from the upper left, the upper right, the lower left, and the lower right may also be sufficient, for example.

In the writing step (S106) of the modified example 3, first, the writing data processing unit 70 interchanges irradiation time data to be in the order of shots, based on the writing sequence having been set. The irradiation time data is stored in the storage device 142. Then, the transmission processing unit 74 transmits irradiation time data, in the order of shots, from the storage device 142 to the deflection control circuit 130.

Based on a plurality of bitmaps A, B, C, and D, the writing mechanism 150 performs writing to the pixels 36 in two or more stripe regions 32-1 and 32-3 (32-2, 32-4) indicated by data of two or more bitmaps A and C (B, D) in data of a plurality of bitmaps A, B, C and D with a plurality of shots of the same beam in the multiple beams 20, during the same tracking control in a plurality of tracking controls which deflect beams of the multiple beams 20 to follow the movement of the XY stage 105 with the target object 101 thereon.

In other words, according to the modified example 3 of the first embodiment, during the k-th tracking control (k being a natural number), the writing mechanism 150 performs writing to the pixels 36 in two or more stripe regions 32-1 and 32-3 indicated by data of two or more bitmaps A and C, which is a portion of data of a plurality of bitmaps A, B, C, and D, with a plurality of shots of the same beam of the multiple beams 20. Furthermore, during the (k+1)th tracking control, the writing mechanism 150 writes to the pixels 36 in one or more stripe regions 32-2 and 32-4 indicated by data of one or more bitmaps B and D, which is the other portion of the data of the plurality of bitmaps A, B, C, and D, with one or more shots of the same beam of the multiple beams 20.

According to the modified example 3 of the first embodiment, during each tracking control, the writing mechanism 150 writes to the same pixels 36 in the stripe regions 32-1 and 32-3 (32-2, 32-4) indicated by a plurality of bitmaps A and C (B, D) with a plurality of shots of the same beam of the multiple beams 20. In the cases of FIGS. 15 and 16, during the k-th tracking control, the writing mechanism 150 writes to the same pixels 36 in the stripe regions 32-1 and 32-3 indicated by the two bitmaps A and C with two shots of the same beam of the multiple beams 20. Furthermore, during the (k+1)th tracking control, the writing mechanism 150 writes to the same pixels 36 in the stripe regions 32-2 and 32-4 indicated by the two bitmaps B and D with two shots of the same beam of the multiple beams 20.

Specifically, it operates as described below. As shown in FIG. 15, during the first tracking control, the shot 1 applies a beam to the pixel at the lower left of each sub-irradiation region 29, using the bitmap A, and the shot 2 applies the same beam as that of the shot 1 to the same pixel 36, using the bitmap C. The shot position of the multiple beams 20 of each shot during each tracking control is adjusted by beam deflection by the sub deflector 209. After these two shots, tracking is reset.

Similarly, during the second tracking control, the shot 3 applies a beam different from those of the shots 1 and 2 to the pixel at the lower left of each sub-irradiation region 29, using the bitmap B, and the shot 4 applies the same beam as that of the shot 3 to the same pixel 36, using the bitmap D. After these two shots, tracking is reset.

Similarly, during the third tracking control, the shot 5 applies a beam, which is different from those of the shots 1 to 4, to the pixel at the lower right of each sub-irradiation region 29, using the bitmap A, and the shot 6 applies the same beam as that of the shot 5 to the same pixel 36, using the bitmap C. After these two shots, tracking is reset.

Similarly, during the fourth tracking control, the shot 7 applies a beam, which is different from those of the shots 1 to 6, to the pixel at the lower right of each sub-irradiation region 29, using the bitmap B, and the shot 8 applies the same beam as that of the shot 7 to the same pixel 36, using the bitmap D. After these two shots, tracking is reset.

Similarly, during the fifth tracking control, the shot 9 applies a beam, which is different from those of the shots 1 to 8, to the pixel at the upper left of each sub-irradiation region 29, using the bitmap A, and the shot 10 applies the same beam as that of the shot 9 to the same pixel 36, using the bitmap C. After these two shots, tracking is reset.

Similarly, during the sixth tracking control, the shot 11 applies a beam, which is different from those of the shots 1 to 10, to the pixel at the upper left of each sub-irradiation region 29, using the bitmap B, and the shot 12 applies the same beam as that of the shot 11 to the same pixel 36, using the bitmap D. After these two shots, tracking is reset.

Similarly, during the seventh tracking control, the shot 13 applies a beam, which is different from those of the shots 1 to 12, to the pixel at the upper right of each sub-irradiation region 29, using the bitmap A, and the shot 14 applies the same beam as that of the shot 13 to the same pixel 36, using the bitmap C. After these two shots, tracking is reset.

Similarly, during the eighth tracking control, the shot 15 applies a beam, which is different from those of the shots 1 to 14, to the pixel at the upper right of each sub-irradiation region 29, using the bitmap B, and the shot 16 applies the same beam as that of the shot 15 to the same pixel 36, using the bitmap D. After these two shots, tracking is reset.

As a result of the above-described, writing to all the pixels 36 in the rectangular region 35 is completed. By proceeding the writing process similarly, the whole of the stripe regions 32-1, 32-2, 32-3, and 32-4 can be written. By similarly writing to the stripe region of each row, the whole of the writing region 30 of the target object 101 is completely written.

According to the modified example 3 of the first embodiment, the same pixels in two of four bitmaps are written with the same beam during the same tracking control. The same pixels in the other two bitmaps can be written with a beam adjacent to the current beam during a tracking control performed subsequent to the current one. Accordingly, gray level errors can be reduced.

The examples described above show the case where, for example, two bitmaps are shifted in the y direction, but it is not limited thereto.

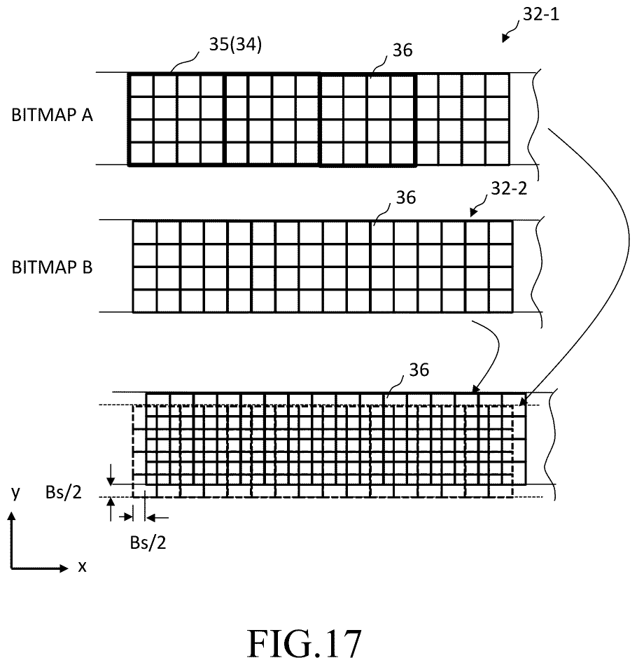

FIG. 17 is an illustration showing another example of a plurality of bitmaps according to the first embodiment. FIG. 17 shows the two bitmaps A and B. The positions of the two bitmaps A and B are shifted from each other in the x and y directions by ½ of the size of the pixel 36. Also, in such a case, gray level errors can be reduced. Alternatively, the positions of the two bitmaps A and B may be shifted from each other in the x direction by ½ of the size of the pixel 36.

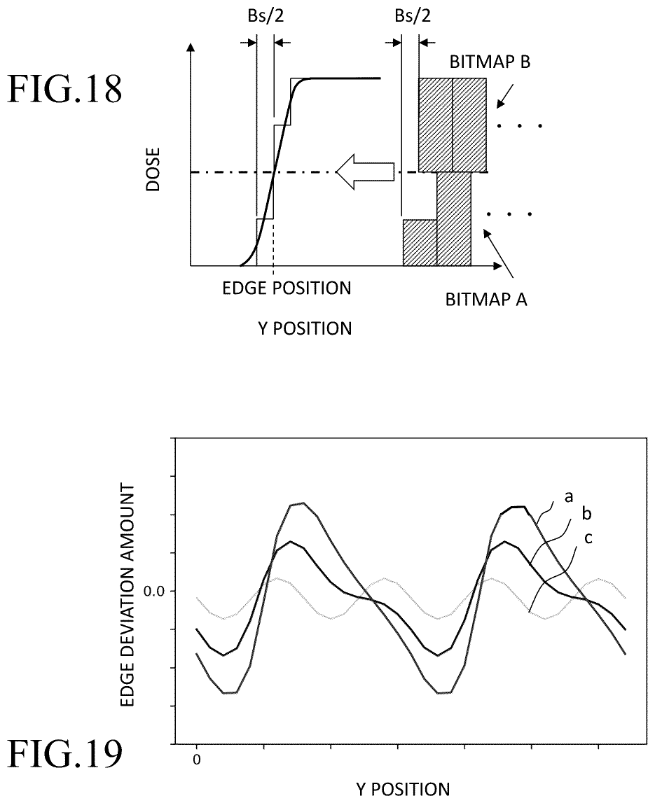

FIG. 18 is an illustration showing an example of a relationship between a dose and a position when a bitmap is shifted according to the first embodiment. In FIG. 18, the ordinate axis represents a dose, and the abscissa axis represents a y-direction position. FIG. 18 shows the case where two bitmaps are used. The two bitmaps are shifted from each other in the y direction by ½ of the size of the pixel 36. At the pattern edge portion, in the bitmap A, writing is performed by applying ¼ of the dose to the pixel at the edge position and ½ of the dose to the right adjacent pixel, and in the bitmap B which is shifted from the bitmap A in the right (y direction) by ½ of the size of the pixel 36, writing is performed by applying ½ of the dose to the pixel at the edge position and ½ of the dose to the right adjacent pixel. Since the total dose of the bitmaps A and B is applied to the edge portion, the minimum unit of the gray-scale value representing the edge portion can be subdivided from the pixel size to its ½ substantially. Since the subdividing can increase the resolution, gray level errors can be reduced. However, gray level errors can be reduced only when the actual overlay between the bitmaps is not shifted, or the shifted amount is small. If the overlay between the bitmaps is shifted, a desired reduction effect against gray level errors cannot be acquired. Even if there is no overlay deviation in the design, when the irradiation position of an actual beam deviates, the reduction effect against gray level errors cannot be acquired.

FIG. 19 is a graph showing an example of a relationship between an edge deviation amount and a position according to the first embodiment. In FIG. 19, the ordinate axis represents an amount of edge deviation, and the abscissa axis represents a y-direction position. In the graph, the line a shows the case where the irradiation position of the actual beam is shifted by 2 nm, the line b shows the case where the irradiation positions of the actual beam is shifted by 1 nm, and the line c shows the case where there is no deviation (0 nm) of the irradiation position of the actual beam. As shown in FIG. 19, it turns out that when the irradiation position of the actual beam deviates from the design pixel position indicated by the bitmap, the amount of edge deviation becomes large according to the deviation amount of the irradiation position.

As described above, according to the first embodiment, it is possible to reduce a deviation between the design position of a pixel and the irradiation position of an actual beam in multiple beam writing employing the bitmap shift method. Accordingly, the amount of edge deviation can be reduced.

Embodiments have been explained referring to specific examples described above. However, the present invention is not limited to these specific examples.

While the apparatus configuration, control method, and others not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any other multi-charged particle beam writing apparatus, multi-charged particle beam writing method, and program that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
generating bitmap data defining values each depending on a dose of each pixel of a plurality of pixels, for each of a plurality of writing regions, on a target object, each of which is composed of meshed-divided regions being the plurality of pixels and which are offset from each other by a size equal to or smaller than a size of the each pixel; and
performing writing, based on two or more bitmap data in a plurality of bitmap data having been generated, to pixels each being in a different one of writing regions each corresponding to one of the two or more bitmap data with a plurality of shots of a same beam in multiple charged particle beams during one tracking control, while repeating a cycle of resetting a deflection amount after each tracking control for deflecting the multiple charged particle beams in order to follow a movement of a stage on which the target object is placed.

2. The method according to claim 1, wherein, in the writing, writing to same pixels each being in the different one of the writing regions each corresponding to the one of the two or more bitmap data is performed during the one tracking control.

3. The method according to claim 1, wherein, in the writing, writing to different pixels each being in the different one of the writing regions each corresponding to the one of the two or more bitmap data is performed during the one tracking control.

4. The method according to claim 1, wherein, in the writing,
during a first tracking control being the one tracking control, writing to pixels each being in a different one of two or more stripe regions of a plurality of stripe regions is performed with a first beam of the multiple charged particle beams, based on one of two or more bitmap data of the plurality of bitmap data for the plurality of stripe regions, and
during a second tracking control, being the one tracking control, performed one of before and after the first tracking control, writing to one or more pixels in another one or more stripe regions of the plurality of stripe regions is performed with the first beam, based on another one or more bitmap data of the plurality of bitmap data for the plurality of stripe regions.

5. The method according to claim 4, wherein,
the plurality of stripe regions are formed by dividing the plurality of writing regions in a direction linearly independent of a movement direction of the stage, the plurality of stripe regions being offset from each other by a size equal to or smaller than that of a pixel, and
the first tracking control and the second tracking control are provided so as to be switched for each writing of at least any one of the plurality of stripe regions.

6. A non-transitory computer-readable storage medium storing a program for causing a computer to execute processing, comprising:
generating bitmap data defining values each depending on a dose of each pixel of a plurality of pixels, for each of a plurality of writing regions, on a target object, each of which is composed of meshed-divided regions being the plurality of pixels and which are offset from each other by a size equal to or smaller than a size of the each pixel;
storing a plurality of bitmap data having been generated in a storage device; and
reading the plurality of bitmap data from the storage device, and controlling, based on two or more bitmap data in the plurality of bitmap data, a writing mechanism to perform writing to pixels each being in a different one of writing regions each corresponding to one of the two or more bitmap data with a plurality of shots of a same beam in multiple charged particle beams during one tracking control, while repeating a cycle of resetting a deflection amount after each tracking control for deflecting the multiple charged particle beams in order to follow a movement of a stage on which the target object is placed.
